(19) United States
(12) Patent Application Publication
(10) Pub. No.: US 2005/0183663 A1
(43) Pub. Date: Aug. 25, 2005

(54) Systems and methods for manufacture of carbon nanotubes

(76) Inventors: Shang-Che Cheng, San Jose, CA (US); Paul A. Dennig, San Jose, CA (US)

Correspondence Address: PERKINS COIE LLP, P.O. BOX 2168, MENLO PARK, CA, 94026, US

(21) Appl. No.: 10/984,214

(22) Filed: Nov. 8, 2004

Related U.S. Application Data
(60) Provisional application No. 60/518,233, filed on Nov. 7, 2003.

(51) Int. Cl. C23C 16/00

(52) U.S. Cl. 118/715

(57) ABSTRACT

A horizontally-disposed reaction tube for generating multi-walled carbon nanotubes is described. Gaseous reactants and very fine solid catalyst particles are introduced into the horizontally-disposed reaction tube, and chemical reactions take place to grow multi-wall carbon nanotubes on the catalyst particles.

### CLAIM OF PRIORITY

This application claims priority to U.S. Provisional Application No.: 60/518,233, entitled SYSTEMS AND METHODS FOR MANUFACTURE OF CARBON NANOTUBES, filed Nov. 7, 2003, which is hereby incorporated by reference in its entirety.

### FIELD OF THE INVENTION

This invention relates to the field of materials science, and more particularly, to carbon nanotubes.

### DESCRIPTION OF PRIOR ART

Carbon may be instantiated in the form of nanotubes (CNTs), and this form of carbon has received much attention in recent years, as these materials possess a number of interesting properties, particularly related to their electrical conductivity/resistivity, and their ability to switch properties under different stimuli or environments. These materials appear to have particular applications in the emerging field of nanotechnology. Indeed the name “nanotubes” reflects the relative size of these materials, which ordinarily have diameters on the order of nanometers. Carbon nanotubes may be single-walled or double-walled.

The prior art details a number of methods of producing carbon nanotubes and particularly single wall carbon nanotubes (SWCNTs). There remains a need for efficient, high-quality, and cost-effective techniques for the manufacture of multi-walled carbon nanotubes (MWCNTs). This inadequacy in the prior art is addressed by the present invention.

### SUMMARY OF THE INVENTION

The present invention is based on a horizontally-disposed reaction tube for the generation of carbon nanotubes. In embodiments of the invention, gaseous reactants and very fine solid catalyst particles are introduced into the horizontally-disposed reaction tube, and chemical reactions take place to grow Multi-Wall Carbon Nanotubes (MWCNTs) on the catalyst particles. In embodiments of the invention, the reactions include one or more of the following steps: (i) thermal decomposition of the reactant gases on the catalyst, (ii) accumulation of carbon in the catalyst, and (iii) the subsequent growth of the MWCNTs outwards from the catalyst particles. This is often referred to as chemical vapor deposition (CVD), whereby a material (MWCNT) is created by exposing a solid (the unsupported catalytic particles) to a specific composition of reactant gases at a prescribed temperature and pressure. Advantages of the present invention include rapid growth rate of the carbon nanotube materials, as well as the high product purity of the carbon nanotube end-product, both in terms of its structure and composition. These and other aspects of the invention are further described herein.

### BRIEF DESCRIPTION OF THE FIGURES

FIG. 1 illustrates an apparatus for manufacturing carbon nanotubes in accordance with embodiments of the invention.

FIG. 2 illustrates an internal view of the carbon nanotube manufacturing apparatus, in accordance with embodiments of the invention.

FIG. 3 illustrates a chemical vapor deposition furnace, in accordance with embodiments of the invention.

FIG. 4 illustrates a side view of a chemical vapor deposition furnace in accordance with the embodiments of the invention.

FIG. 5 illustrates a reaction tube for a carbon nanotube manufacturing apparatus, in accordance with the embodiments of the invention.

FIG. 6 illustrates a catalyst feeder for inserting catalysts into a carbon nanotube manufacturing system in accordance with embodiments of the invention.

FIG. 7 illustrates a feedstock feeder for combining gaseous components into a reaction tube for the CNT manufacturing system, in accordance with embodiments of the invention.

FIG. 8 illustrates a method for synthesizing carbon nanotubes, in accordance with embodiments of the invention.

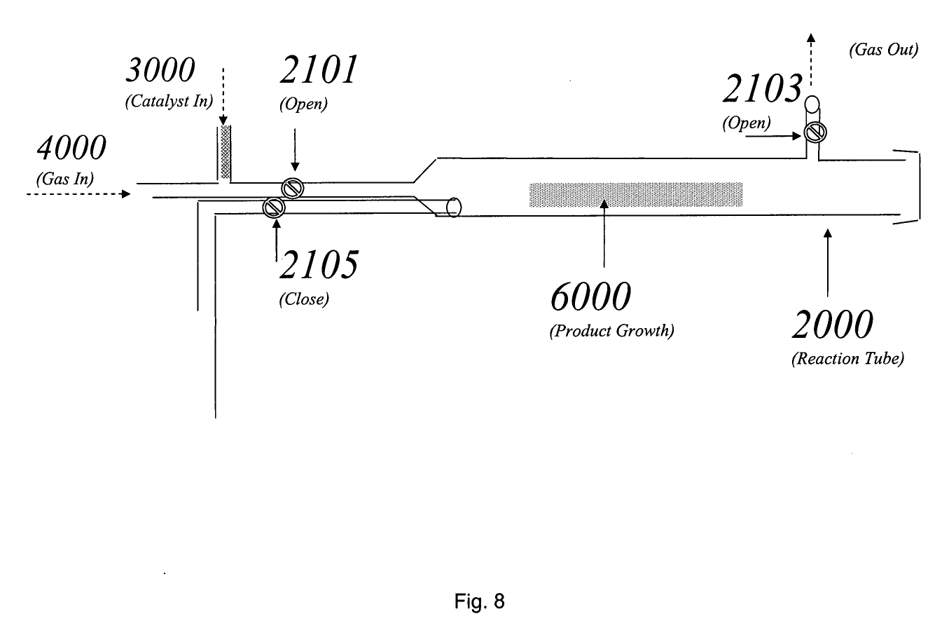

FIG. 9 illustrates a system for collecting CNT from a CNT manufacturing system, in accordance with the embodiments of the invention.

FIG. 10 illustrates an alternate system for collecting CNT from a CNT manufacturing system, in accordance with the embodiments of the invention.

FIG. 11 illustrates yet another alternative system for collecting CNT from a CNT manufacturing system, in accordance with the embodiments of the invention.

### DETAILED DESCRIPTION OF THE INVENTION

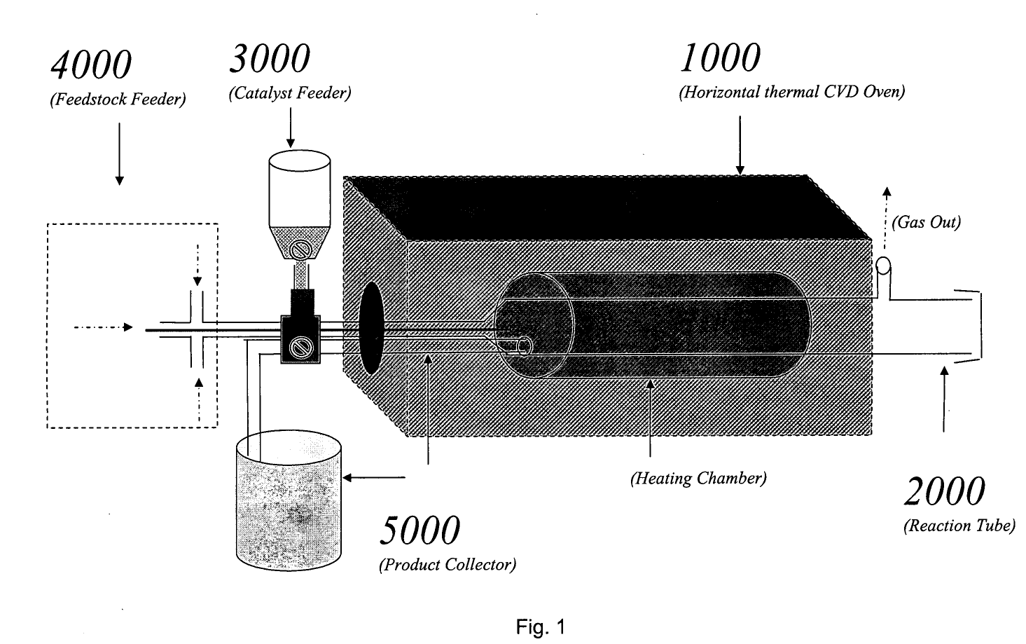

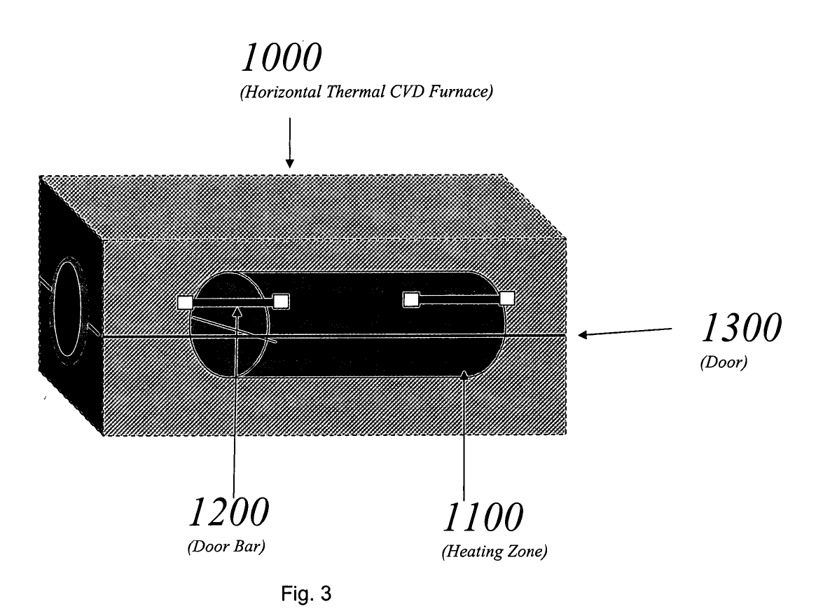

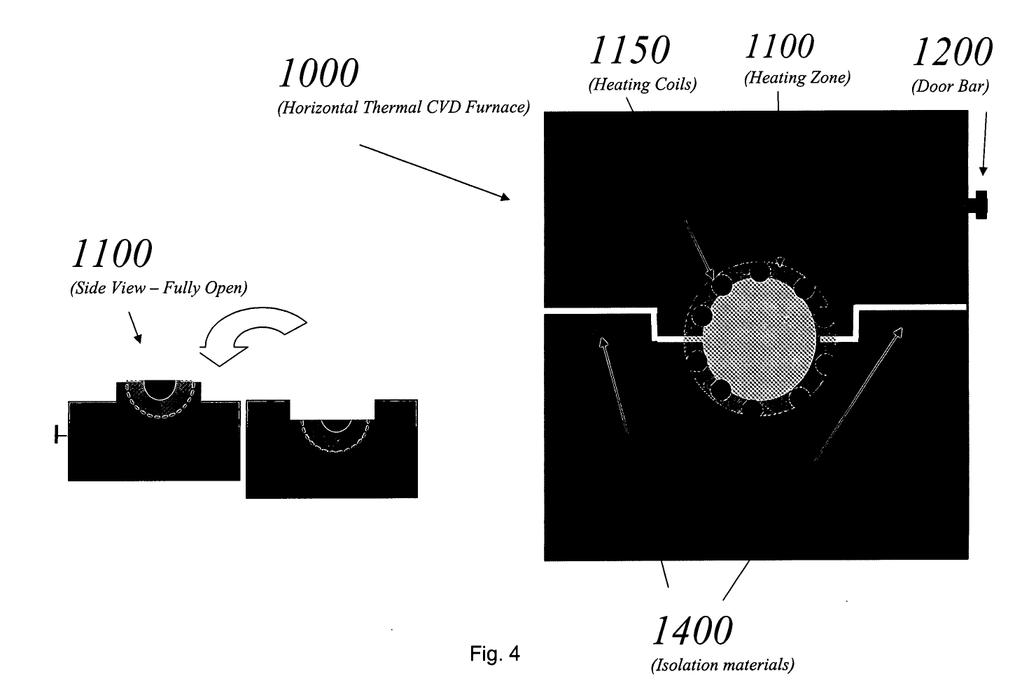

FIG. 1 illustrates an apparatus for manufacturing multi-walled carbon nanotubes. The apparatus includes a horizontally-disposed chemical vapor deposition (CVD) furnace, or “oven”. The CVD 1000 also includes a reaction tube 2000, and supplies uniform heat for driving the reaction that generates the MWCNT. As shown in FIG. 3 and FIG. 4, the CVD furnace 1000 may include a heating zone 1100, which, in embodiments, comprises a region of constant elevated temperature. The heating zone 1100 may be heated by use of heating coils 1150. In embodiments of the invention, these heating coils operate by transforming electrical energy to heat through coiled resistance wires. In some embodiments, the CVD finance 1000 may also include a door 1300 and a door bar, or handle 1200, which may be used to access the contents 2000 of the CVD 1000. In some embodiments of the invention, the CVD furnace 1000 may further include thermal isolation materials 1400, which help maintain uniform temperature.

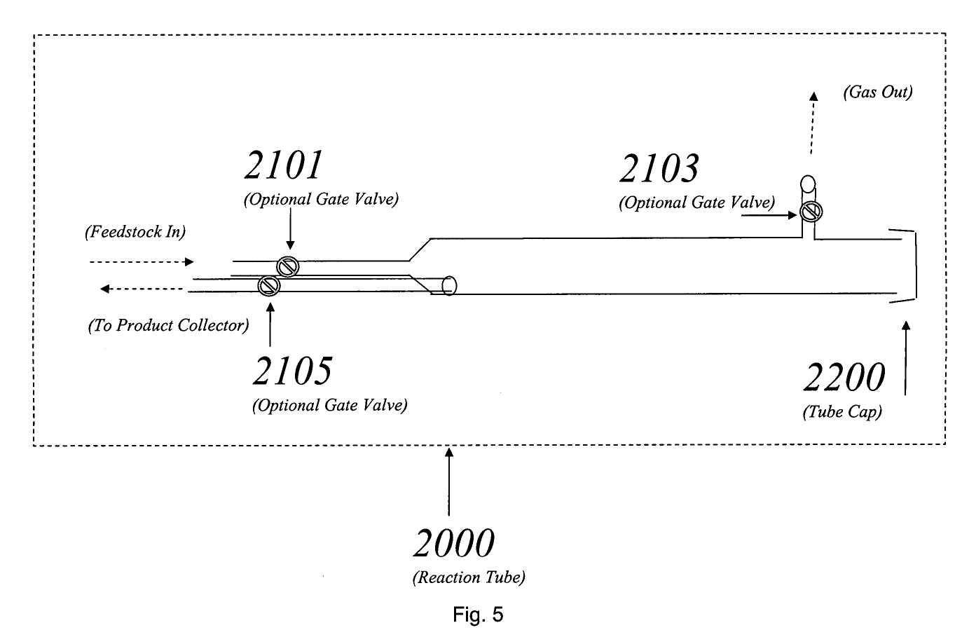

FIG. 1 also depicts a reaction tube 2000, in which the MWCNTs are grown. As shown in FIG. 5, some embodiments of the invention may include an optional gate valve 2101, which allows chemical feedstock to flow in (gas and catalyst). Some embodiments may also include another optional gate valve 2103, which allows gaseous byproducts and unconsumed reactant gases to exit the reaction tube. Embodiments may also include an additional optional gate valve 2105, which allows product 6000 retrieval to take place, as further discussed herein. FIG. 5 further depicts a tube cap 2200. In some embodiments, this tube is normally closed, but may be opened for maintenance or alternative product retrieval.

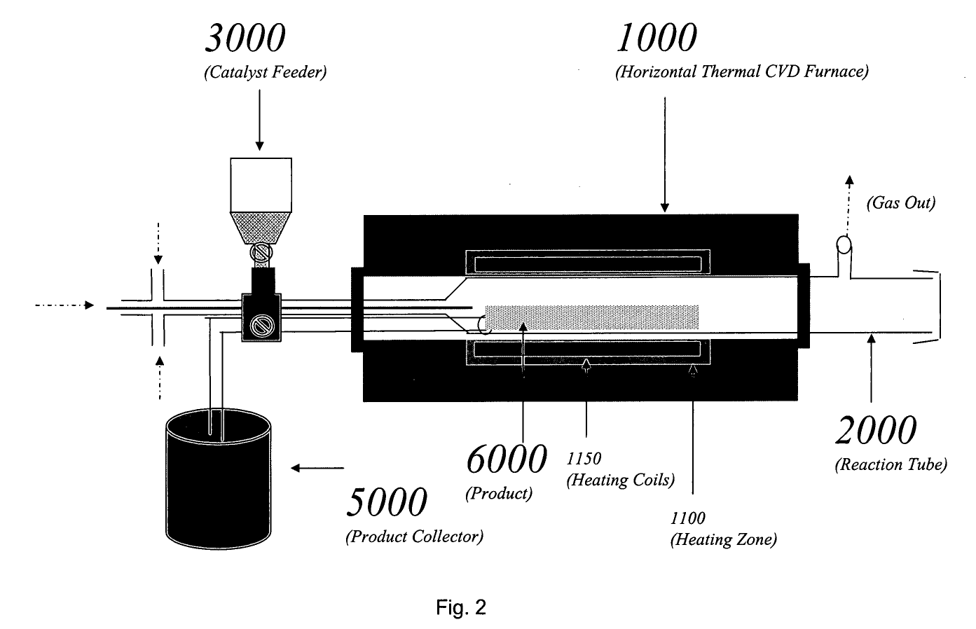

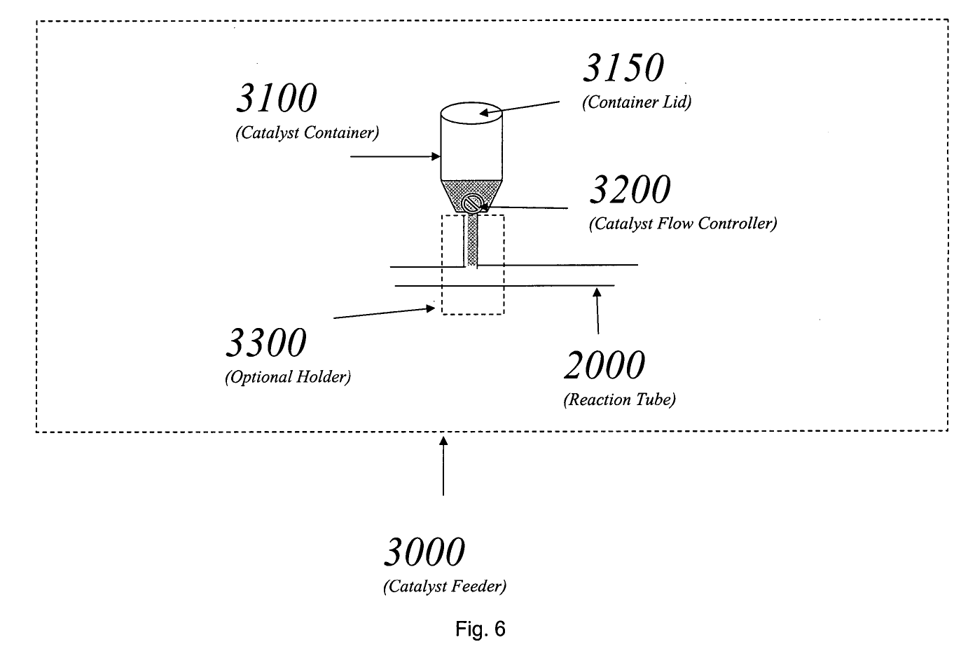

Embodiments of the invention also include a catalyst feeder 3000, as depicted in FIG. 2. By way of non-limiting example, this catalyst feeder 3000 may comprise a “Hopper” style container, which feeds a little catalyst at a time into the incoming gas stream. Additional features of the catalyst feeder 3000 are shown in FIG. 6, such as a Catalyst container 3100, which holds the catalyst for the MWCNT producing reaction, in accordance with embodiments of the invention. Also depicted are a container lid 3150 affixed to a top of the catalyst feeder 3000. In embodiments, the catalyst feeder is attached to a catalyst flow controller 3200, which controls a rate at which the catalyst is fed into a gas stream. Also depicted in FIG. 6 are an optional holder, for supporting the catalyst container 3100, container lid 3150, and catalyst flow controller 3200, in accordance with embodiments of the invention.

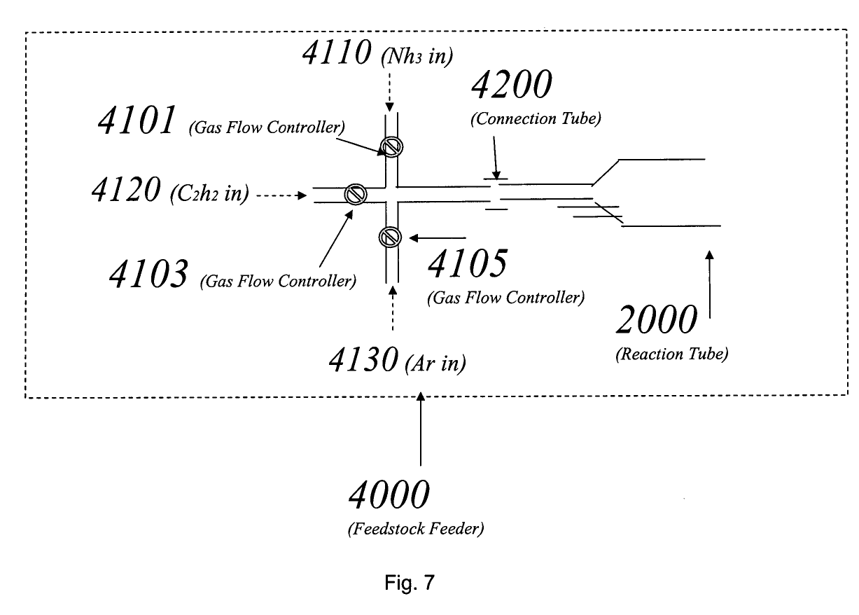

FIG. 7 illustrates a feedstock feeder 4000, often referred to as an “intake manifold.” As used in embodiments of the invention, the feedstock feeder 4000 may combine several gaseous components to allow one entry point into the reaction tube. The feedstock feeder 4000 may further include a gas flow controller 4101, to control a rate at which a gas such as NH3 (ammonia) is entered into the reaction tube. In embodiments the feedstock feeder 4000 may also include a gas flow controller 4103 to control the rate of C2H2 (acetylene) addition to the reaction tube. In embodiments, the feedstock feeder also includes another gas flow controller 4105, which controls the rate of Ar (argon) added to the reaction tube. FIG. 7 also illustrates the addition of particular gases into the reaction tube, such as NH₃ 4110, C₂H₂ 4120, and Ar 4130. A tube connector 4200 may join the gas manifold to reaction tube 2000.

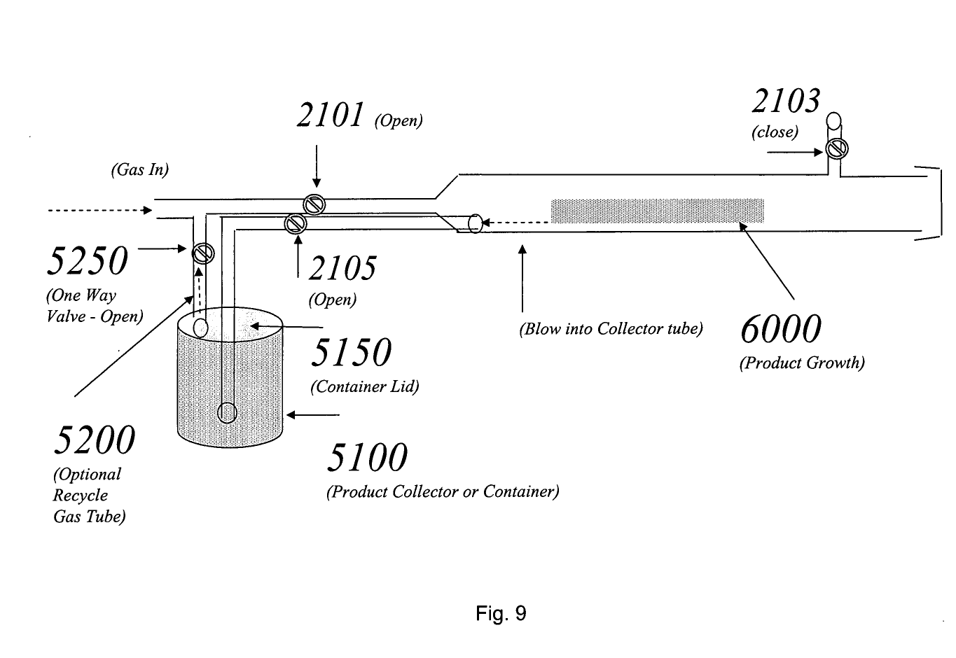

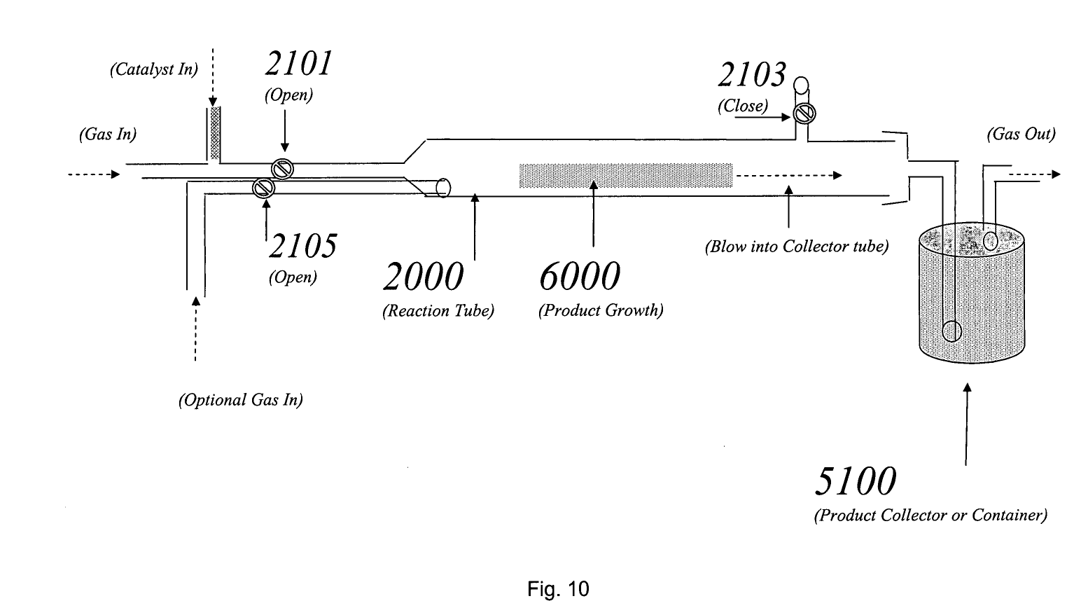

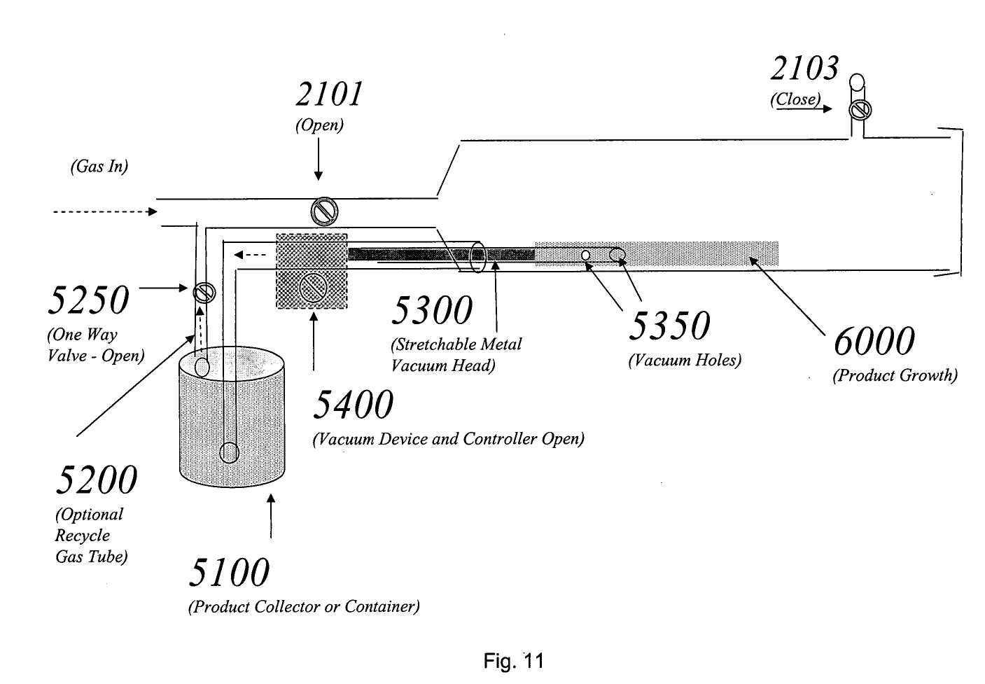

FIGS. 9, 10, and 11 depict embodiments for collection of the end product MWCNT from the system. A product collector 5000 comprises a mechanism and container to collect and temporarily store the MWCNT product. By way of non-limiting examples, this collector 5000 may comprise a vacuum tube; other suitable containers shall be readily apparent to those skilled in the art. Some embodiments of the invention may include a product collector or container 5100 which allows for the product to transported out by vacuum (‘pneumatic transport’) and the process gases to be recycled through an optional recycling gas tube 5200 on the intake side. Another embodiment allows gas through 2105 to blow the product out, where it could be collected in 5100 on the exit end of the process tube. Also depicted in FIG. 9 is a container lid 5150, along with a one-way valve 5250. As shown in FIG. 11, embodiments of the invention may include an expandable vacuum head 5300. By way of non-limiting example, this vacuum head may be made of an expandable material, such as a metal. Other suitable materials for the vacuum head shall be apparent to those skilled in the art. Embodiments of the invention may also include vacuum intake holes 5350, which vacuums up the product from the floor of the reaction tube. Alternatives to the vacuum process may include a mechanical device, such as an Archimedes screw, and other alternatives shall be apparent to those skilled in the art. Also depicted in FIG. 11 is a vacuum device and controller, along with the end product MWCNTs 6000.

1. A system for manufacturing multi-walled carbon nanotubes, the system comprising:
a horizontally-disposed chemical vapor deposition furnace, the horizontally disposed furnace further including a reaction tube to drive a reaction that generates the multi-walled carbon nanotubes, such that the furnace heats the reaction tube to generate the multi-walled carbon nanotubes;
a catalyst feeder for inserting one or more catalysts to a gas stream entering the reaction tube to produce the reaction to grow the multi-walled carbon nanotubes on the one or more catalysts;
a catalyst flow controller for controlling an amount of the one or more catalysts fed into the reaction tube;
a feedstock feeder for combining one ore more gases to feed into the gas stream, wherein the one or more gases include one or more of ammonia, Argon, and acetylene.

2. The system of claim 1 further including one or more gas controllers coupled to the feedstock feeder for controlling a rate at which the one or more gases is entered into the gas stream.

3. The system of claim 1, wherein the reaction tube is coupled to a product collector for collecting the multi-walled carbon nanotubes produced by the reaction.

4. The system of claim 3, wherein the product collector includes a vacuum tube for collecting and storing the multi-walled carbon nanotubes.

5. The system of claim 4, wherein the product collector is operative to transport unused gases for recycling through the reaction tube.

6. The system of claim 4 further including an expandable vacuum head at an ingress of the vacuum tube.

7. The system of claim 6, wherein the expandable vacuum head is made of a metallic material.

8. The system of claim 3, wherein the product collector includes an Archimedes screw for collecting the multi-walled carbon nanotubes created by the reaction.
